(19) United States
(12) Patent Application Publication
(10) Pub. No.: US 2016/0134249 A1
(43) Pub. Date: May 12, 2016

(54) LAMINATE RF CHOKE FOR FLIP-CHIP POWER AMPLIFIER

(71) Applicant: Morfis Semiconductor, Inc., Irvine, CA (US)

(72) Inventors: Haitao Li, Irvine, CA (US); Changli Chen, Irvine, CA (US)

(21) Appl. No.: 14/932,863

(22) Filed: Nov. 4, 2015

Related U.S. Application Data
(60) Provisional application No. 62/076,418, filed on Nov. 6, 2014.

(51) Int. Cl. H01P 1/00; H03F 1/02; H03F 3/21; H03F 1/56; H03F 3/19

(52) U.S. Cl. CPC H03F 1/565; H03F 1/0205; H03F 3/19; H03F 3/21; H03F 2200/451; H03F 2200/294

(57) ABSTRACT

A circuit includes a flip-chip die and a laminate substrate. The flip-chip die includes a first bump and a second bump. A first metal layer is disposed on the laminate substrate. The first metal layer includes a first transmission line having a plurality of segments forming a first spiral inductor. A first end of the first transmission line is electrically coupled to the first bump. A second end of the first transmission line is electrically coupled to a first power supply pin.

### CROSS-REFERENCE TO RELATED APPLICATIONS

This application relates to and claims the benefit of U.S. Provisional Application No. 62/076,418, filed Nov. 16, 2014 and entitled “LAMINATE RF CHOKE FOR FLIP-CHIP POWER AMPLIFIER” the entirety of the disclosure of which is wholly incorporated by reference herein.

### STATEMENT RE: FEDERALLY SPONSORED RESEARCH/DEVELOPMENT

Not Applicable

### BACKGROUND

1. Technical Field

The present disclosure generally relates to the field of electronics. More particularly, the present disclosure relates to a radio-frequency choke for a flip-chip power amplifier.

2. Related Art

Wireless communication devices may include front-end circuitry for processing or conditioning RF signals at an incoming or outgoing frequency or signal port. RF front-end circuits may be components of receiver, transmitter, or transceiver systems associated with a wireless device.

As a general example, wireless communication devices may be composed of a transmit chain and a receive chain, with the antenna and the transceiver circuit being a part of both the transmit chain and receive chain. The transmit chain may additionally include a power amplifier for increasing the output power of the generated RF signal from the transceiver, while the receive chain may include a low-noise amplifier for boosting the weak received signal so that information can be accurately and reliably extracted therefrom.

The low-noise amplifier and the power amplifier may together consist of a front-end module or front-end circuit, which also includes an RF switch circuit that selectively interconnects the power amplifier and the low-noise amplifier to the antenna. The connection to the antenna is switchable between the receive chain circuitry (i.e., the low-noise amplifier and the receiver) and the transmit chain circuitry (i.e., the power amplifier and the transmitter). In time domain duplex (TTD) communications systems where a single antenna is used for both transmission and reception, switching between the receive chain and the transmit chain occurs rapidly many times throughout a typical communications session.

The amplifier circuits of the front-end module are typically manufactured as an integrated circuit (IC). In high-power applications such as GSM (Global System for Mobile communications) handsets, WLAN (wireless local area networking) client interface devices and infrastructure devices, the ICs are typically manufactured with a GaAs (gallium arsenide) semiconductor substrate.

Inductors are used in many ICs intended for RF applications. For example, on-chip inductors with high Quality factor (Q factor) are widely used in voltage controlled oscillators, low noise amplifiers and other RF building blocks. An inductor may operate as an RF choke, i.e., the inductor may be electrically open at high RF frequencies used for communication by the device.

Inductor elements in RF integrated circuits (RFICs) are commonly made of flat or planar loops fabricated through conventional lithographic processes. RF inductors can occupy a large portion of the available IC die area, therefore, it is desirable to achieve the maximum possible level of compactness and efficiency in their design and fabrication. The benefits of highly-integrated circuit designs include, among other things, smaller circuit size, improved circuit matching, precise control of component layout, and the availability of multiple active components within a small design package.

In the field of telecommunications, for example, the RF power amplifier output matching network is one of the most crucial components to meet the design targets for impedance, power, efficiency, and harmonic suppression. The RF choke part of the network is typically within 1 nH to 3 nH (nanoHenry) in a cellular phone power amplifier application to provide enough isolation to RF energy.

A robust power distribution network is essential to ensure reliable operation of circuits on a chip. Due to the resistance of the interconnect structures constituting the network, there is a voltage drop across the network, commonly referred to as the IR drop. The RF choke part of the network needs to be high Q to minimize the IR drop for direct current (DC) supply.

RFICs are currently being utilized across a broad range of industries, e.g., aerospace, military, telecom, test & measurement, and medical electronics industries, and have utility in many applications. There is a continuing need in the art for improved inductor designs for RFICs.

### BRIEF SUMMARY

The present disclosure is directed to a flip-chip die over laminate structure.

According to an aspect of the present disclosure, there is circuit including a flip-chip die and a laminate substrate. The flip-chip die includes a first bump and a second bump. A first metal layer is disposed on the laminate substrate. The first metal layer includes a first transmission line having a plurality of segments forming a first spiral inductor. A first end of the first transmission line is electrically coupled to the first bump. A second end of the first transmission line is electrically coupled to a first power supply pin.

According to another aspect of the present disclosure, there is a circuit. The circuit includes a flip-chip die and a laminate substrate. The flip-chip die includes a die substrate, a metal layer disposed on the die substrate, a first bump connected to the metal layer, and a second bump connected to the metal layer. A first transmission line is disposed on the laminate substrate and forms a first spiral inductor. The first transmission line includes a first end electrically coupled to the first bump. A second transmission line is disposed on the laminate substrate and forms a second spiral inductor. The second transmission line has a first end electrically coupled to the second bump. A second end of the first transmission line is electrically coupled to a first power supply pin. A second end of the second transmission line is electrically coupled to a second power supply pin.

### BRIEF DESCRIPTION OF THE DRAWINGS

Objects and features of the presently-disclosed flip-chip die over laminate structure will become apparent to those of ordinary skill in the art when descriptions of various embodiments thereof are read with reference to the accompanying drawings, of which:

FIG. 1A is a plan view showing a flip-chip die over laminate structure including two spiral inductors shown in phantom lines in accordance with an embodiment of the present disclosure;

FIG. 1B is an enlarged, plan view of the indicated area of detail of FIG. 1A;

FIG. 2 is a cross-sectional view taken along the lines 2-2 of FIG. 1B illustrating the two spiral inductors on the laminate substrate connected to die bumps in accordance with an embodiment of the present disclosure;

FIG. 3 is a plan view showing a conventional on-die inductor;

FIG. 4 is a plan view showing an on-laminate inductor in accordance with an embodiment of the present disclosure;

FIG. 5 is a plot illustrating inductance variation between the on-die inductor of FIG. 3 and the on-laminate inductor of FIG. 4 in accordance with an embodiment of the present disclosure; and

FIG. 6 is a plot illustrating Q factor variation between the on-die inductor of FIG. 3 and the on-laminate inductor of FIG. 4 in accordance with an embodiment of the present disclosure.

### DETAILED DESCRIPTION

Hereinafter, embodiments of a flip-chip die over laminate structure are described with reference to the accompanying drawings. Like reference numerals may refer to similar or identical elements throughout the description of the figures.

This description may use the phrases “in an embodiment,” “in embodiments,” “in some embodiments,” or “in other embodiments,” which may each refer to one or more of the same or different embodiments in accordance with the present disclosure.

As it is used herein, the term “spiral” is intended to encompass a broad class of structures which exhibit a clockwise or counterclockwise outwardly winding path, e.g., beginning in a substantially centralized location, in which each winding is successively longer than the previous winding. This definition is intended to embody generally rectangular, polygonal, oval, elliptical, and circular spirals as well as other irregular yet generally spiraling shapes. For illustrative purposes, generally rectilinear spirals are shown in the figures.

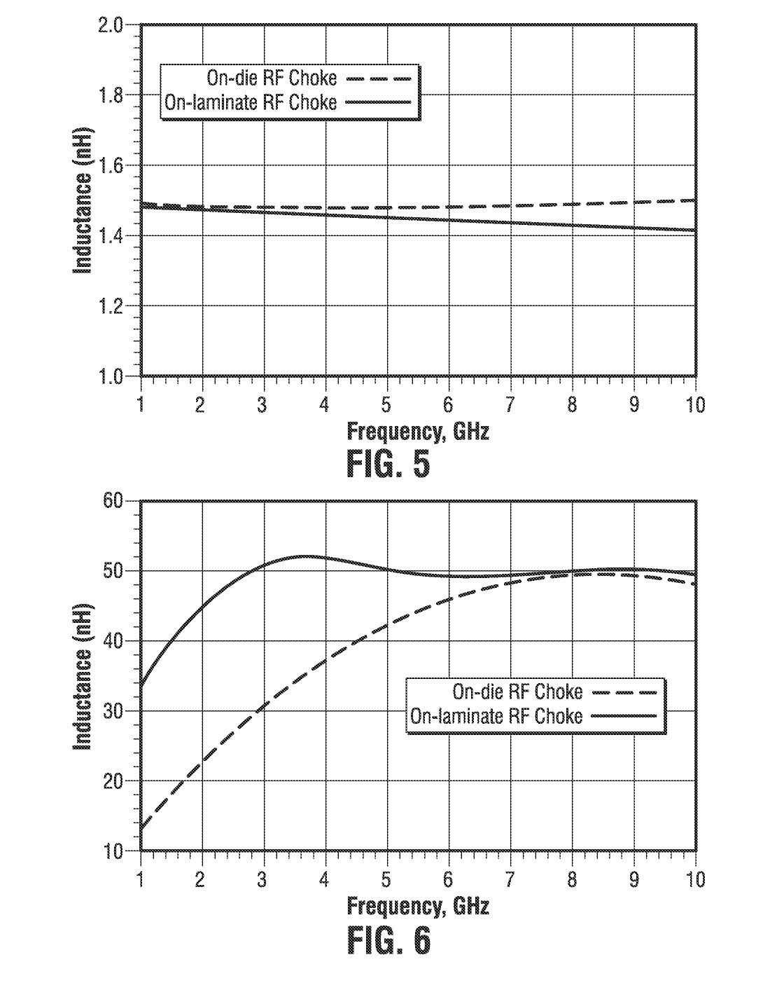

Various embodiments of the present disclosure provide a flip-chip die over laminate structure including one or more spiral inductors. Various embodiments of the present disclosure provide a power amplifier module using a flip-chip power amplifier die and on-laminate RF choke. The presently-disclosed embodiments of on-laminate spiral inductors provide a low-cost realization of an RF choke and may provide improved performance (e.g., as depicted in FIGS. 5 and 6).

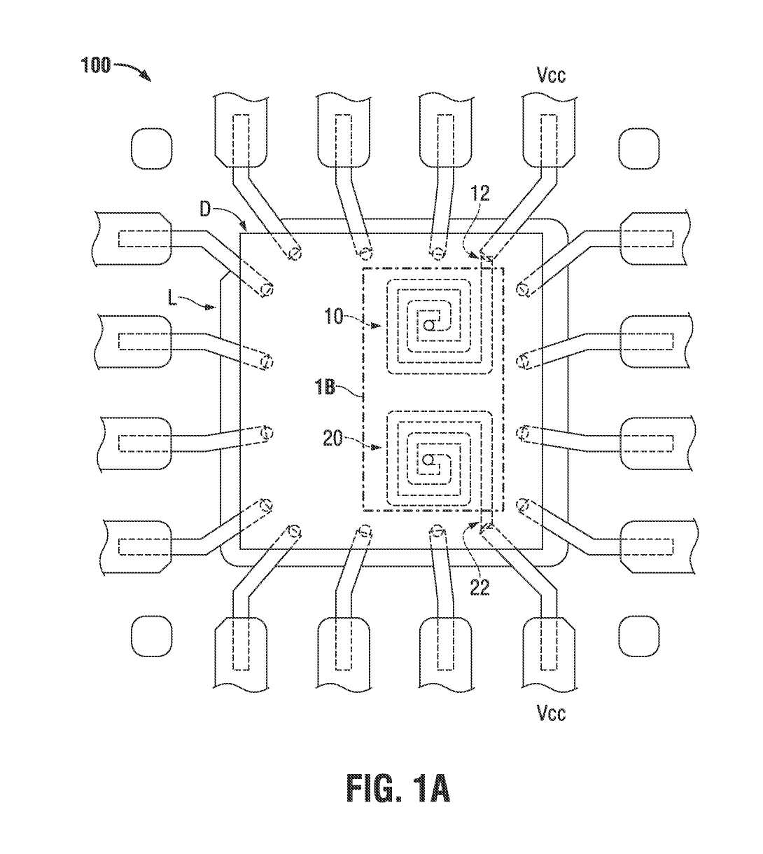

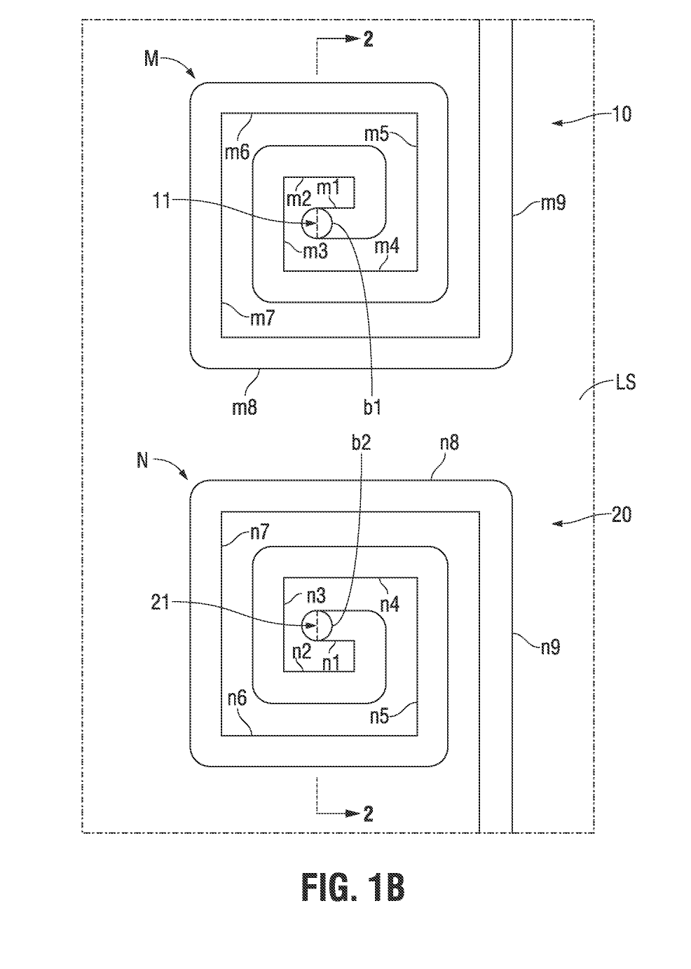

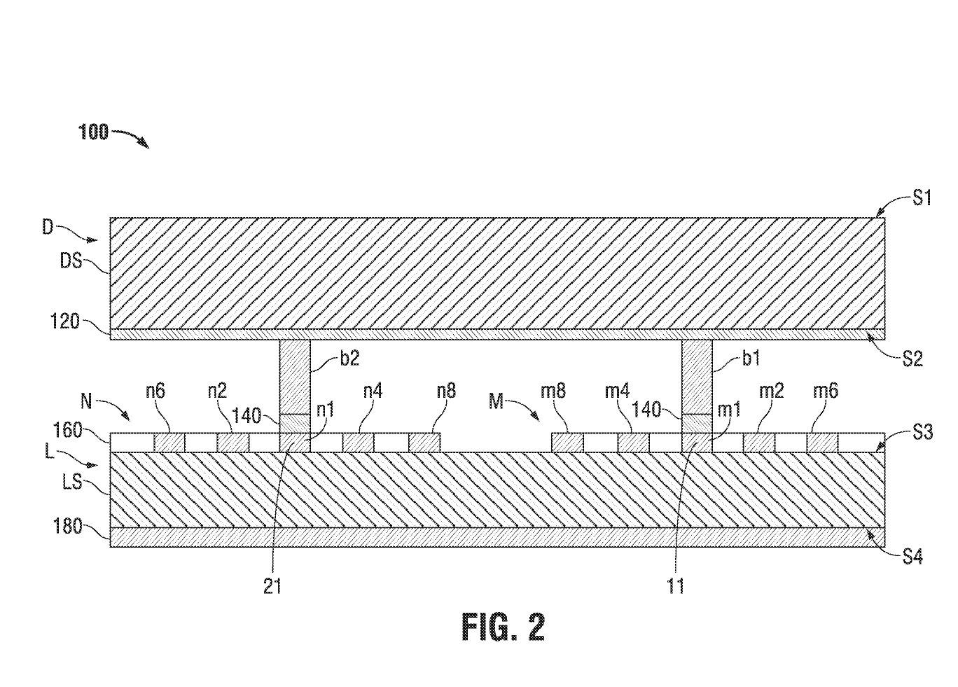

Referring now to FIGS. 1A, 1B and 2, there is a shown structure 100 including a flip-chip die “D” over a laminate “L” in accordance with an embodiment of the present disclosure. As shown in FIG. 2, the flip-chip die “D” includes a die substrate “DS” and a laminate substrate “LS.” The die substrate “DS” has a first side “S1” and a second side “S2.” The laminate substrate “LS” has a first side “S3” and a second side “S4.” A metal layer 120 is disposed on at least a portion of the second side “S2” of the die substrate “DS.” A metal layer 160 is disposed on at least a portion of the first side “S3” of the laminate substrate “LS. In some embodiments, a metal layer 180 is disposed on at least a portion of the second side “S4” of the laminate substrate “LS.” The metal layer 120 on the second side “S2” of the die substrate “DS” is electrically coupled through bumps (e.g., first bump b1 and second bump b2 shown in FIG. 2) to the metal layer 160 on the first side “S3” of the laminate substrate “LS.” In some embodiments, an electrically-conductive material, e.g., solder 140, may be disposed between the bumps b1 and b2 and the metal layer 160. The metal layer 160 includes a first spiral inductor 10 and a second spiral inductor 20.

As shown in FIG. 2, the first spiral inductor 10 is formed by a first transmission line “M” having a plurality of segments, and the second spiral inductor 20 is formed by a second transmission line “N” having a plurality of segments. The first transmission line “M” forming the first spiral inductor 10 includes a first end 11 and a second end 12. In some embodiments, the first transmission line “M” includes a first segment “m1,” a second segment “m2,” a third segment “m3,” a fourth segment “m4,” a fifth segment “m5,” a sixth segment “m6,” a seventh segment “m7,” an eighth segment “m8,” and a ninth segment “m9.” In the illustrative embodiment shown in FIG. 1B, the first spiral inductor 10 has a substantially rectilinear spiral shape, e.g., partially defined by the first segment “m1,” the second segment “m2,” the fourth segment “m4,” the sixth segment “m6,” and the eighth segment “m8,” which are arranged in parallel and spaced apart from each other, and partially defined by the third segment “m3,” the fifth segment “m5,” seventh segment “n7,” and the ninth segment “m9,” which are arranged in parallel and spaced apart from each other (and arranged perpendicular to the first, second, fourth, sixth, and eighth segments “m1,” “m2,” “m4,” “m6,” and “m8”).

The second transmission line “N” forming the second spiral inductor 20 includes a first end 21 and a second end 22. In some embodiments, the second transmission line “N” includes a first segment “n1,” a second segment “n2,” a third segment “n3,” a fourth segment “n4,” a fifth segment “n5,” a sixth segment “n6,” a seventh segment “n7,” an eighth segment “n8,” and a ninth segment “n9.” The first transmission line “M” forming the first spiral inductor 10 and the second transmission line “N” forming the second spiral inductor 20 may include straight line segments, curvilinear line segments, angular line segments, etc.

As shown in FIG. 1A, the second end 12 of the first spiral inductor 10 is electrically coupled to a first power supply pin “Vcc” and the second end 22 of the second spiral inductor 20 is electrically coupled to a second power supply pin “Vcc.” As shown in FIGS. 1B and 2, the first end 11 of the first spiral inductor 10 is electrically coupled to the first bump b1 of the flip-chip die “D,” and the first end 21 of the second spiral inductor 20 is electrically coupled to the second bump b2 of the flip-chip die “D.”

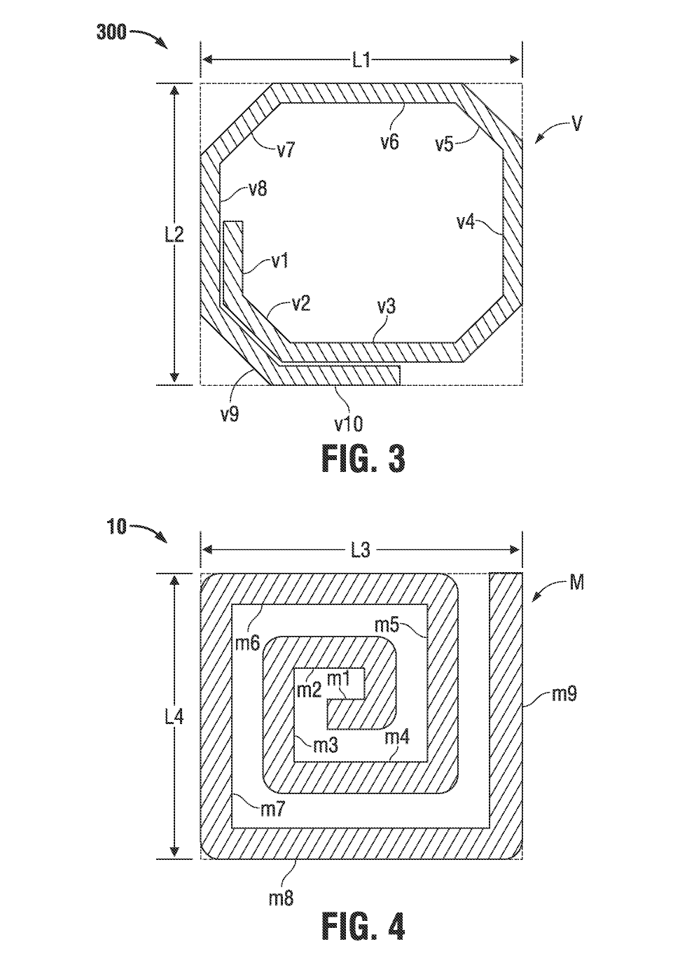

FIG. 3 shows a conventional on-die spiral inductor 300. The spiral inductor 300 is formed by a transmission line “V” having a plurality of segments. In the illustrative example depicted in FIG. 3, the transmission line “V” includes a first segment “v1,” a second segment “v2,” a third segment “v3,” a fourth segment “v4,” a fifth segment “v5,” a sixth segment “v6,” a seventh segment “v7,” an eighth segment “v8,” a ninth segment “v9,” and a tenth segment “v10.”

As shown in FIG. 3, the on-die spiral inductor 300 has a width “L1” and a height “L2.” In an illustrative example, where “L1”=407 μm and “L2”=382 μm, the on-die spiral inductor 300 has an area “L1”×“L2”=0.155 mm².

FIG. 4 shows the spiral inductor 10 formed by the first transmission line “M.” As shown in FIG. 4, the spiral inductor 10 has a width “L3” and a height “L4.” In an illustrative example, where “L3”=510 μm and “L4”=455 m, the on-laminate spiral inductor 10 has an area “L3”×“L4”=0.232 mm².

FIG. 5 shows a plot of frequency (GHz) versus inductance (nH) between the on-die spiral inductor shown in FIG. 3 operating as an RF choke (as indicated by the dashed line in FIG. 5) and the on-laminate spiral inductor 10 shown in FIG. 4 operating as an RF choke (as indicated by the solid line in FIG. 5). As depicted in FIG. 5, the spiral inductor 300 and the spiral inductor 10 both have inductance of around 1.47 nH from 1 GHz to 3 GHz.

FIG. 6 shows a plot of frequency (GHz) versus Q factor between the on-die spiral inductor shown in FIG. 3 operating as an RF choke (as indicated by the dashed line in FIG. 5) and the on-laminate spiral inductor 10 shown in FIG. 4 operating as an RF choke (as indicated by the solid line in FIG. 5). As depicted in FIG. 6, the on-laminate RF choke has higher Q than the on-die RF choke.

Although embodiments have been described in detail with reference to the accompanying drawings for the purpose of illustration and description, it is to be understood that the disclosed processes and apparatus are not to be construed as limited thereby. It will be apparent to those of ordinary skill in the art that various modifications to the foregoing embodiments may be made without departing from the scope of the disclosure. Further, the various features of the embodiments disclosed herein can be used alone, or in varying combinations with each other and are not intended to be limited to the specific combination described herein. Thus, the scope of the claims is not to be limited by the illustrated embodiments.

What is claimed is:

1. A circuit, comprising:
a flip-chip die including a first bump and a second bump;
a laminate substrate; and
a first metal layer disposed on the laminate substrate, the first metal layer including:
a first transmission line having a plurality of segments forming a first spiral inductor, the first transmission line having a first end electrically coupled to the first bump;
wherein a second end of the first transmission line is electrically coupled to a first power supply pin.

2. The circuit of claim 1, wherein the first metal layer further includes a second transmission line having a plurality of segments forming a second spiral inductor, the second transmission line having a first end electrically coupled to the second bump.

3. The circuit of claim 2, wherein a second end of the second transmission line is electrically coupled to a second power supply pin.

4. The circuit of claim 1, wherein the flip-chip die is a flip-chip power amplifier die.

5. The circuit of claim 3, wherein the first spiral inductor formed by the plurality of segments of the first transmission line has a substantially rectilinear shape.

6. A circuit, comprising:
a flip-chip die including a die substrate, a metal layer disposed on the die substrate, a bump connected to the metal layer, and a second bump connected to the metal layer;
a laminate substrate;
a first transmission line disposed on the laminate substrate and forming a first spiral inductor, the first transmission line having a first end electrically coupled to the first bump; and
a second transmission line disposed on the laminate substrate and forming a second spiral inductor, the second transmission line having a first end electrically coupled to the second bump;
wherein a second end of the first transmission line is electrically coupled to a first power supply pin, and wherein a second end of the second transmission line is electrically coupled to a second power supply pin.

7. The circuit of claim 6, wherein the flip-chip die is a flip-chip power amplifier die.

8. The circuit of claim 6, wherein the first transmission line forming the first spiral inductor includes a plurality of segments.

9. The circuit of claim 8, wherein the first spiral inductor formed by the plurality of segments of the first transmission line has a substantially rectilinear shape.

10. The circuit of claim 8, wherein the plurality of segments of the first transmission line includes a first segment, a second segment, a third segment, a fourth segment, a fifth segment, a sixth segment, a seventh segment, an eighth segment, and a ninth segment.

11. The circuit of claim 6, wherein the first transmission line forming the first spiral inductor includes a plurality of segments.

12. The circuit of claim 11, wherein the first spiral inductor formed by the plurality of segments of the first transmission line has a substantially rectilinear shape.
